(19) United States
(12) Patent Application Publication
(10) Pub. No.: US 2003/0183170 A1
(43) Pub. Date: Oct. 2, 2003

(54) Plasma processing apparatus

(75) Inventors: Tatsuya Kato, Shizuoka-ken (JP); Masashi Kando, Shizuoka-ken (JP)

Correspondence Address: Finnegan, Henderson, Farabow,, Garrett & Dunner, L.L.P., 1300 I Street, N.W., Washington, DC, 20005-3315, US

(73) Assignee: YAZAKI CORPORATION

(21) Appl. No.: 10/396,352

(22) Filed: Mar. 26, 2003

(30) Foreign Application Priority Data
Mar. 26, 2002 (JP) P 2002-086837

(51) Int. Cl. C23C 16/00; H01L 21/306

(52) U.S. Cl. 118/723 MW; 118/723 MP; 118/723 AN; 156/345.38; 156/345.41; 118/718

(57) ABSTRACT

A plasma processing apparatus includes a generator for producing a first microwave. The apparatus includes a slot antenna for receiving the first microwave to radiate a second microwave in a shape. The apparatus includes a dielectric window for receiving the second microwave to produce surface-wave plasma. The apparatus includes a conveyor for an object to pass in proximity to the dielectric window. The apparatus includes a transmitting path for transmitting the first microwave in a direction. The apparatus includes a coaxial converter provided to a front end of the transmitting path. The coaxial converter includes an internal conductor for converting the first microwave from the direction into an orthogonal direction relative to the transmission path. The apparatus includes a discharging chamber provided to the dielectric window.

### BACKGROUND OF THE INVENTION

The present invention relates to a plasma processing apparatus, and to one, which processes, for example, a resinous insulator of a wire.

Conventionally, the technique in the Japanese Patent Application Publication After Examination No. Syou59-53646 is known. The technique is that irradiation of electron rays on a resin insulator activates crosslinkage. The technique is directed to the enlarging of a crosslinked layer of the insulator. Specifically, between the irradiating source of electron rays and a cable, a metal plate with a hole is located. An application of a voltage with a direct current to a conductor of the cable as positive and to the metal plate as negative prevents accumulation of electrons in the insulator. This increases electron rays in depth of transmission.

Another technique, or the plasma processing apparatus in Japanese Patent Application Laid-open Publication NO. Hei10-60140, is known. The apparatus includes a negative electrode and canned role located opposite to each other in a decompressed container. The canned role function as an earth electrode. A high voltage of direct current is applied between them to produce Argon (Ar) plasma. A base to be processed is fed from a feed role over the canned role, and is wound into a winding role.

### SUMMARY OF THE INVENTION

The former method, however, employs a large-scale apparatus, which causes a high productive cost. The fixing of electron rays in direction of irradiation makes it difficult to irradiate electron rays on the cable over the periphery from all directions.

The latter apparatus processes the base over the entire periphery with Ar plasma. However, discharge of a direct current causes the shortening of a battery's lifetime. A metal is produced from the electrode due to spattering, which causes pollution.

The invention is directed to a plasma processing apparatus, which successively processes an insulator of a wire over the entire surface, and prevents pollution on a metal.

The invention is directed to a plasma processing apparatus. The apparatus includes a generator for producing a first microwave. The apparatus includes a slot antenna for receiving the first microwave to radiate a second microwave in a shape. The apparatus includes a dielectric window for receiving the second microwave to produce surface-wave plasma. The apparatus includes a conveyor for an object to pass in proximity to the dielectric window.

Preferably, the apparatus includes a transmitting path for transmitting the first microwave in a direction. The apparatus includes a coaxial converter provided to a front end of the transmitting path. The coaxial converter includes an internal conductor for converting the first microwave from the direction into an orthogonal direction relative to the transmission path. The apparatus includes a discharging chamber provided to the dielectric window. The slot antenna is joined to an end of the internal conductor. The slot antenna is attached with the dielectric window.

Preferably, the slot antenna includes a central part. The antenna includes an annular part in a circle concentric with the central part for enclosing the central part. The antenna includes a slot between the central part and the annular part

Preferably, the dielectric window includes a silica plate

Preferably, the conveyor includes a pair of rollers for feeding and winding up the object.

Preferably, the object includes an electric wire. The electric wire includes a conductor, and an insulator covering the conductor.

### BRIEF DESCRIPTION OF THE ACCOMPANYING DRAWINGS

FIG. 1 is a side view of the plasma processing according to the embodiment of the invention;

FIG. 2 is a sectional view of a discharging chamber in FIG. 1;

FIG. 3A is a plane view of a slot antenna in FIG. 1; and

FIG. 38 is a sectional view taken along IIIB-IIIB line in FIG. 3A.

### DETAILED DESCRIPTION OF THE PREFERRED EMBODIMENTS

The plasma processing apparatus of the present invention will hereby be described with reference to the drawings.

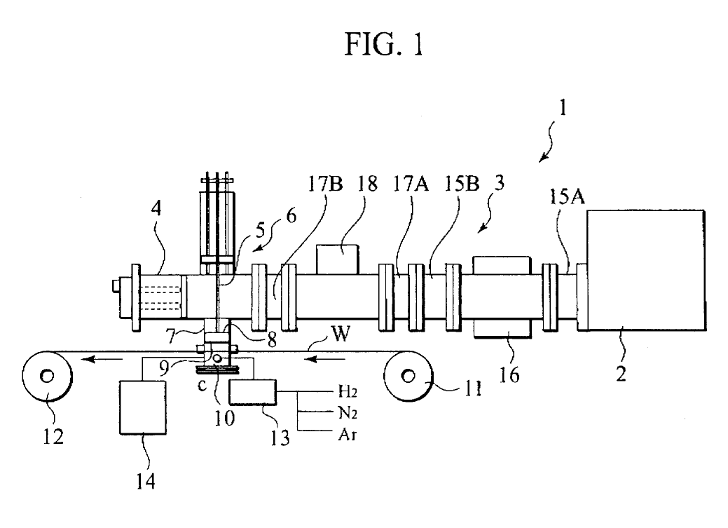

In FIG. 1, plasma processing apparatus 1 includes generator 2 for producing a microwave. Apparatus 1 includes transmission path 3 for transmitting the microwave. Apparatus 1 includes rectangular wave-guide 4, which is connected to path 3 at the front end. Wave-guide 4 has an H-wave or a TE-wave (transverse electric wave) for passing therethrough. Apparatus 1 includes coaxial converter 6 provided to wave-guide 4. Converter 6 includes an internal conductor 5, which passes therethrough normal to wave-guide 4. Converter 6 converts the microwave from an H-wave into a TEM-wave (transverse electric and magnetic wave). Apparatus 1 includes a coaxial line path 7 of an aluminum (aluminium) pipe, which is provided to converter 6 at the lower part. Apparatus 1 includes a slot antenna 8 provided to internal conductor 5 at the lower end. Apparatus 1 includes with silica window 9 or a dielectric attached to slot antenna 8 on the bottom surface. Silica window 9 transmits a microwave therethrough. A part of transmitted microwave advances on the surface of window 9. Apparatus 1 includes a discharging chamber 10 spaced from coaxial line path 7, with silica window 9 intervening between them. Apparatus 1 includes a pair of rollers 12. Rollers 12 feed and wind up wire W or a member to be processed, which passes directly below silica window 9. Apparatus 1 includes gas controller 13 for feeding a gas into discharging chamber 10. Apparatus 1 includes vacuum evacuator 14 for evacuating discharging chamber 10.

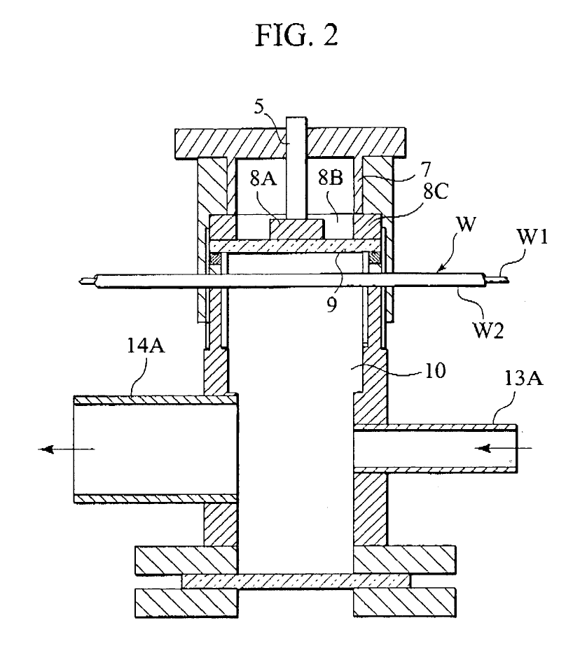

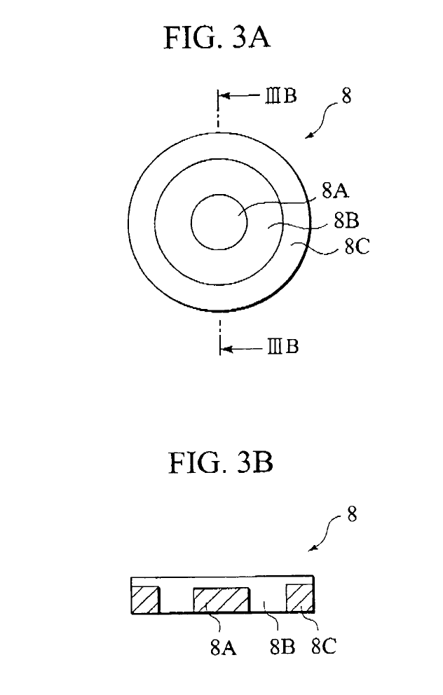

Slot antenna 8 and silica window 9 tightly contact with each other. Antenna 8, in FIGS. 3A and 3B, includes a disc-shaped central part 8A located at the central portion. Antenna 8 includes concentric-circular annular part 8C enclosing the central part 8A. Central and annular parts 8A and 8C includes predetermined slit or slot 8B between them. In FIGS. 1 and 2, central part 8A has the center on the top surface, which is connected to internal conductor 5 at the lower end at a right angle. Slot 8B establishes a width with a range of, for example, 12.5 mm to 15.0 mm, which allows high energy efficiency.

Transmitting path 3 includes directional coupling 15A joined to generator 2. Transmitting path 3 includes isolator 16 joined to directional coupling 15A. Transmitting path 3 includes transformer 17A joined to directional coupling 15B at the front end. Transmitting path 3 includes automatic matching device 18 at the front of transformer 17A. Transmitting path 3 includes transformer 17B at the front of matching device 18.

Transmitting path 3 transmits a microwave in an H01 wave. Coaxial converter 6 is configured to covert the microwave from an H01-wave to a TEM-wave. The microwave in a TEM-wave is introduced into discharging chamber 10 to produce a plasma. The plasma is a surface-wave plasma. Electric wire W is set to pass through a region where the surface-wave plasma is produced. In FIG. 2, discharging chamber 10 is joined to a gas controller through gas introducing pipe 13. Evacuator 14 is joined to discharging chamber 10 through evacuating pipe 14A. Adjustment of controller 13 and evacuator 14 allows control of plasma on a productive condition. Maintaining an environment within a decompression system such as discharging chamber 10 needs a sealant such as a bellows seal or an O-ring, disposed at adequate positions.

The surface-wave plasma means a wave to transmit along the interface between two media. The surface-wave plasma transmits on a boundary surface between a high density plasma layer with equal to or more than a cut-off frequency and a dielectric or silica window 9. When an electric field on a surface-wave occurs with intensity enough to ionize a neutral particle or atom, the surface-wave transmits, as producing plasma. The production of plasma employs a microwave in either a standing wave or a pulse wave. Especially, the pulse wave allows processing at a lower temperature than the standing wave, even with a great incident energy.

Apparatus 1, to produces such surface-wave plasma, allows production of plasma in a plane plate-shape with a large area. Non-electrode discharge allows for a discharger with long lifetime and for flexibly shaped plasma. No magnetic field for retaining produced plasma reduces the device in productive cost.

In apparatus 1, slot antenna 8 is examined in a shape for radiating energy most efficiently, as respective kinds of shapes are altered. In FIGS. 3A and 3B, annular slot 8B spaces central part 8A and circular annular part 8C from each other. Slot 8B, with a width of a range between 12.5 mm and 15.0 mm, has the most excellent energy efficiency, and allows production of stable plasma. An object to be processed and a plasma resource are examined in a positional relationship therebetween at an input power of 600 W. As a result, it is confirmed that slot 8B with even a width of about 60 mm obtains an effect of plasma processing, and enhances insulator's characteristics (provided that the positional relationship is varied by input power of the microwaves to vary optimum condition).

In FIG. 2, electric wire W includes conductor W1, and resinous insulator W2 covering conductor W1. Device 1 passes electric wire W, with conductor W1 covered with resinous insulator W2, through the region directly below silica window 9. This allows insulator W2 on the surface to be successively processed. The surface-wave plasma allows free design of plasma in shape, allowing plasma processing in accordance with the configuration of an object to be processed. The processing with surface-wave plasma allows insulator W2 on the surface to be uniformly processed, and facilitates crosslinking, and imparting a characteristic improvement in water-sheddablity or wettability.

Although the invention has been described above by reference to certain embodiments of the invention, the invention is not limited to the embodiments described above. Modifications and variations of the embodiments described above will occur to those skilled in the art, in light of the above teachings. The scope of the invention is defined with reference to the following claims.

An object to be processed may adopt, for example, another object covered with a resin or a rubber, other than wire W.

The embodiment may be adapted to a recycle process where a wire is fused on the insulator for taking out the conductor.

Although microwave transmitting path 3 includes a plurality of members, the invention is not limited to the joining configuration.

According to the invention, the object to be processed is moved in proximity to the dielectric window. The movement allows the object on the surface to be uniformly processed by the surface-wave plasma, which achieves, for example, crosslinking and water-shedding. The slot antenna as non-discharging electrode extends a discharger's lifetime, and prevents production of spattered objects.

The invention allows plasma to be produced in a predetermined shape.

The invention allows an object to be successively plasma processed.

The invention allows plasma processing of the wire on a resinous insulator to improve crosslinking, water-shedding or wettability.

The entire contents of Japanese Patent Applications P2002-086837 (filed on Mar. 26, 2002) are incorporated herein by reference.

What is claimed is:

1. A plasma processing apparatus comprising:
a generator for producing a first microwave;
a slot antenna for receiving the first microwave to radiate a second microwave in a shape;
a dielectric window for receiving the second microwave to produce surface-wave plasma; and a conveyor for an object to pass in proximity to the dielectric window.

2. The plasma processing apparatus according to claim 1, further comprising:
a transmitting path for transmitting the first microwave in a direction;
a coaxial converter provided to a front end of the transmitting path, the coaxial converter including an internal conductor for converting the first microwave from the direction into an orthogonal direction relative to the transmission path; and
a discharging chamber provided to the dielectric window,
wherein the slot antenna is joined to an end of the internal conductor,
wherein the slot antenna is attached with the dielectric window.

3. The plasma processing apparatus according to claim 1,
wherein the slot antenna comprises,
a central part;
an annular part in a circle concentric with the central part for enclosing the central part; and
a slot between the central part and the annular part.

4. The plasma processing apparatus according to claim 1, wherein the dielectric window comprises a silica plate.

5. The plasma processing apparatus according to claim 1,
wherein the conveyor comprises a pair of rollers for feeding and winding up the object.

6. The plasma processing apparatus according to claim 1,
wherein the object comprises an electric wire,
the electric wire comprises,
a conductor; and
an insulator covering the conductor.
